(19) United States
(12) Patent Application Publication
(10) Pub. No.: US 2005/0218115 A1
(43) Pub. Date: Oct. 6, 2005

(54) Anti-clogging nozzle for semiconductor processing

(75) Inventors: Lawrence Chung-Lai Lei, Milpitas, CA (US); Siqing Lu, San Jose, CA (US); Steven E. Gianoulakis, Pleasanton, CA (US); Irene Chou, San Jose, CA (US); David P. Sun, Mountain View, CA (US)

Correspondence Address: APPLIED MATERIALS, INC.;Legal Affairs Department, Patent Counsel, M/S 2061, P.O. Box 450A, Santa Clara, CA, 95052, US

(73) Assignee: Applied Materials, Inc., Santa Clara, CA (US)

(21) Appl. No.: 11/080,387

(22) Filed: Mar. 14, 2005

Related U.S. Application Data
(63) Continuation-in-part of application No. 10/934,213, filed on Sep. 3, 2004.
(60) Provisional application No. 60/542,577, filed on Feb. 6, 2004.

(51) Int. Cl. G01L 21/30; H01L 21/302

(52) U.S. Cl. 216/59; 438/706; 156/345.33

(57) ABSTRACT

Embodiments of the present invention are directed to reducing clogging of nozzles and to reducing flow variance through the nozzles in a semiconductor processing chamber. In one embodiment, a method of introducing a gas into a semiconductor processing chamber comprises providing a nozzle having a proximal portion connected to a chamber wall or a gas distribution ring of the semiconductor processing chamber and a distal portion oriented inwardly away from the chamber wall into an interior of the semiconductor processing chamber. The nozzle includes a proximal end coupled with a gas supply. The nozzle includes a nozzle opening at a distal end. The nozzle includes a nozzle passage extending from the proximal end to the distal end. The method further comprises flowing a gas from the gas supply through the proximal end, the nozzle passage, and the nozzle opening of the nozzle into the interior of the semiconductor processing chamber; and choking the gas flow through the nozzle passage at a choke location which is spaced away from the distal end.

### CROSS-REFERENCES TO RELATED APPLICATIONS

This application is a continuation-in-part of U.S. patent application Ser. No. 10/934,213, filed Sep. 3, 2004, which is based on and claims the benefit of U.S. Provisional Patent Application No. 60/542,577, filed Feb. 6, 2004, the entire disclosures of which are incorporated herein by reference.

### BACKGROUND OF THE INVENTION

The present invention relates generally to semiconductor manufacturing and, more particularly, to nozzles for delivering gases in semiconductor processing chambers.

Chemical vapor deposition (CVD) is a gas reaction process used in the semiconductor industry to form thin layers or films of desired materials on a substrate. Some high density plasma (HDP) enhanced CVD processes use a reactive chemical gas along with physical ion generation through the use of an RF generated plasma to enhance the film deposition by attraction of the positively charged plasma ions onto a negatively biased substrate surface at angles near the vertical to the surface, or at preferred angles to the surface by directional biasing of the substrate surface. One goal in the fabrication of integrated circuits (ICs) is to form very thin, yet uniform films onto substrates, at a high throughput. Many factors, such as the type and geometry of the power source and geometry, the gas distribution system and related exhaust, substrate heating and cooling, chamber construction, design, and symmetry, composition and temperature control of chamber surfaces, and material build up in the chamber, must be taken into consideration when evaluating a process system as well as a process which is performed by the system.

The clogging of nozzles for delivering process gases into the processing chamber can also affect deposition film properties. Certain nozzles, such as HDP CVD nozzles, are subjected to plasma heating inside the chamber. The nozzles, which are typically long ceramic nozzles, can reach temperatures as high as about 800° C. or higher. Current nozzles have flow restrictions or orifices located at the distal tips of the nozzles. A temperature gradient is formed between a low temperature region near the proximal end of the nozzle which is connected to the chamber wall and a high temperature at or near the distal nozzle tip. A pressure gradient is also present as the gas flow from a relatively high pressure region near the proximal end of the nozzle to a low pressure region at the distal nozzle tip. When a decomposable gas such as SiH₄ is flowed through the nozzle into the chamber, the pressure and temperature conditions may be sufficient to break down the gas and deposit silicon or other decomposed materials on the inside wall of the nozzle (e.g., 1-5 Torr, >500° C.). Eventually the nozzle flow will be restricted due to the decomposed gas deposits inside the nozzle.

### BRIEF SUMMARY OF THE INVENTION

Embodiments of the present invention are directed to reducing or preventing clogging of nozzles in a semiconductor processing chamber. Instead of placing a flow restriction at the distal nozzle tip, a choke location for choking the gas flow through the nozzle is moved away from the distal end of the nozzle to a region where the temperature inside the nozzle is cooler, preferably substantially cooler, than the temperature at the nozzle tip. The choke location may be at or near the proximal end of the nozzle which is connected to the chamber wall. The lower temperature prevents or reduces breakdown of the gas flowing through the nozzle, thereby avoiding or minimizing clogging in the nozzle. The larger diameter exhaust portion at the distal nozzle tip can also expand the gas to promote supersonic flow and extend the travel of the gas species closer to the center of the substrate for more effective use of reactants and a controllable deposition profile.

In accordance with an aspect of the present invention, a method of introducing a gas into a semiconductor processing chamber comprises providing a nozzle having a proximal portion connected to a chamber wall or a gas distribution ring of the semiconductor processing chamber and a distal portion oriented inwardly away from the chamber wall into an interior of the semiconductor processing chamber. The nozzle includes a proximal end coupled with a gas supply. The nozzle includes a nozzle opening at a distal end. The nozzle includes a nozzle passage extending from the proximal end to the distal end. The method further comprises flowing a gas from the gas supply through the proximal end, the nozzle passage, and the nozzle opening of the nozzle into the interior of the semiconductor processing chamber; and choking the gas flow through the nozzle passage at a choke location which is spaced away from the distal end.

In some embodiments, the gas flow is choked at or near the proximal end of the nozzle. The gas flow is desirably choked at a region which is lower in temperature than the distal end of the nozzle. Choking the gas flow may comprise providing a flow restriction in the nozzle passage at the choke location, wherein the flow restriction has a size to produce sonic flow or supersonic flow of the gas in the nozzle. Choking the gas flow may comprise providing a flow restriction in the nozzle passage at the choke location, wherein the nozzle passage includes a diffuser region adjacent to and downstream of the flow restriction. The diffuser region comprises a diverging portion distal of the flow restriction. The diverging portion has an angle of about 45° to about 120°.

In specific embodiments, the method further comprises lowering a temperature of the nozzle near the choke location. Lowering the temperature of the nozzle at the choke location comprises providing a region of reduced cross-section disposed near the choke location or between the choke location and the distal end of the nozzle. The method may further comprise applying energy in the interior of the semiconductor processing chamber to produce a temperature gradient in the nozzle which has a higher temperature in the distal portion than in the proximal portion. A temperature at the distal end of the nozzle is substantially higher than a temperature at the proximal portion of the nozzle. The gas is decomposable to form deposit in the nozzle passage. The method may further comprise reducing a pressure in the interior of the semiconductor processing chamber to produce a pressure drop from the proximal end of the nozzle to the distal end of the nozzle. A pressure at the proximal end of the nozzle is substantially higher than a pressure at the distal end of the nozzle.

In accordance with another aspect of the invention, a semiconductor processing apparatus comprises a semiconductor processing chamber and at least one nozzle. Each nozzle has a proximal portion connected to a chamber wall of the semiconductor processing chamber and a distal portion oriented inwardly away from the chamber wall into an interior of the semiconductor processing chamber. The nozzle includes a proximal end configured to be coupled with a gas supply, and a nozzle opening at a distal end. The nozzle includes a nozzle passage extending from the proximal end to the distal end, and a choke location configured to choke the gas flow through the nozzle passage. The choke location is spaced away from the distal end.

### BRIEF DESCRIPTION OF THE DRAWINGS

FIG. 1 is a cross-sectional view of a current nozzle for semiconductor processing;

FIG. 2 is a cross-sectional view of a nozzle according to one embodiment of the present invention;

FIG. 3 is a cross-sectional view of a nozzle according to another embodiment of the invention;

FIG. 4 is a cross-sectional view of a nozzle according to another embodiment of the invention;

FIG. 5 is a cross-sectional view of a nozzle according to another embodiment of the invention;

FIG. 6 is a cross-sectional view of a nozzle according to another embodiment of the invention; and

FIG. 7 is a top plan view schematically illustrating a processing chamber having a plurality of nozzles.

### DETAILED DESCRIPTION OF THE INVENTION

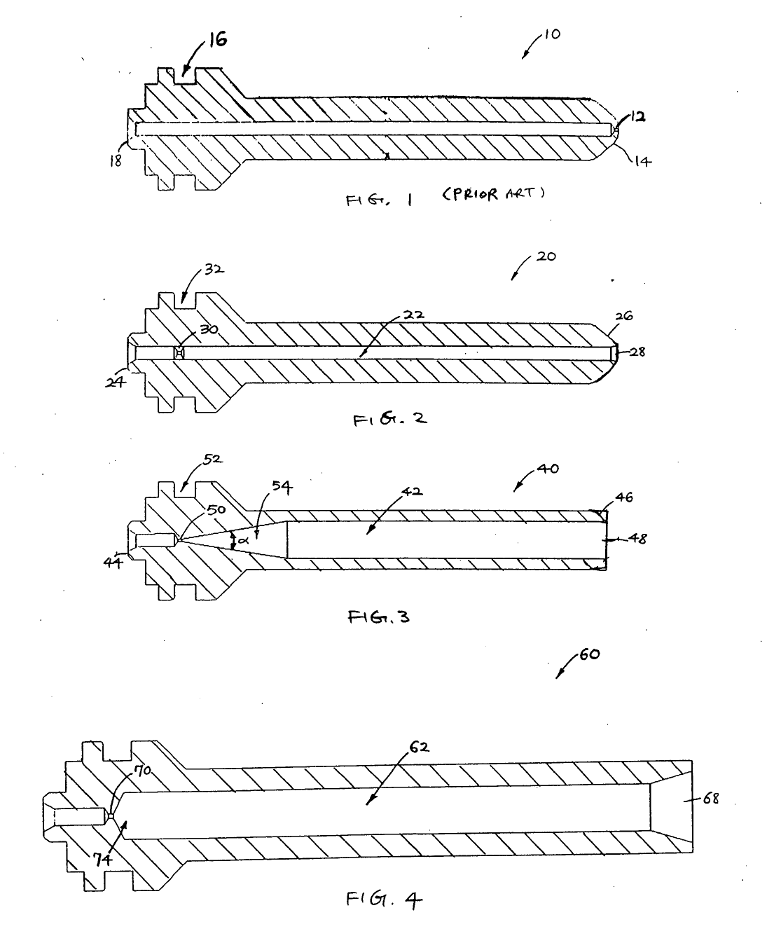

FIG. 1 shows a current nozzle 10 having a flow restriction or orifice 12 disposed at the distal end 14 of the nozzle 10. The nozzle 10 is connected to the chamber wall at a proximal portion 16. Gas is supplied to the nozzle 10 at the proximal end 18. For a semiconductor process such as CVD in which the chamber is heated, the flow restriction 12 is located in a hot section. The temperature decreases from the distal end 14 to the proximal end 18 of the nozzle 10. The pressure typically drops from a high pressure zone near the proximal end 18 to a low pressure zone near the distal end 14 due to the low pressure in the chamber interior on the other side of the flow restriction 12. The gas resident time within the nozzle is relatively long. The gas inside the nozzle is heated due to the increase in temperature upon entering the nozzle 10. The heated gas inside the nozzle is disposed in a relatively high pressure zone proximal or upstream of the flow restriction 12. The relatively high temperature and high pressure can cause gas molecules to break down or dissociate inside the nozzle 10 for a gas that is decomposable. For instance, SiH₄ may break down and form silicon deposits in the nozzle 10 and causes clogging of the nozzle 10. Other gases including metallic components may produce metallic deposits from dissociation.

In FIG. 2, the nozzle 20 has a nozzle passage 22 that extends from the proximal end 24 to the distal end 26. The distal opening 28 is not restricted. The flow restriction 30 is disposed away from the distal end 26, is desirably closer to the proximal end 24 than to the distal end 26, and is more desirably at or near the proximal end 24. In the embodiment shown, the flow restriction 30 is disposed in the proximal region 32 which is connected to the chamber wall or to a water cooled gas distribution ring. As a result, the flow restriction 30 is cooler, desirably much cooler, than the distal region of the nozzle 20, including the distal end 26. For example, the temperature at the distal end 26 may be at least twice the temperature at the proximal portion 32 of the nozzle 20. In an HDP CVD chamber, the temperature may be about 600° C. or higher at the distal end 26 and about 100-200° C. in the proximal region 32 where the flow restriction 30 is located. The pressure in the interior of the chamber is typically much lower than the pressure of the gas near the proximal end 24 of the nozzle 20. For example, the pressure at the proximal end 24 may be at least about 100 times the pressure at the distal end 26 of the nozzle 20. In a typical HDP CVD process, the pressure may be about 2-10 Torr at the proximal end 24 and about 2-10 mTorr at the distal end 26.

Because the flow restriction 30 is disposed in the proximal region 32, the temperature at the flow restriction 30 is substantially lower than the temperature at the distal end 26. In addition, the pressure in the nozzle passage 22 downstream of the flow restriction 30 is lower than in the same region of the nozzle 10 of FIG. 1, including the distal portion where the temperature is high. Thus, the heated gas inside the nozzle passage 22 is disposed in a relatively low pressure zone, so that the gas molecules are less likely to break down or dissociate inside the nozzle 20. Furthermore, the gas resident time in the nozzle 20 of FIG. 2 is much shorter as compared that in the nozzle 10 as a result of moving the flow restriction from the distal end to the proximal region. This also reduces the opportunity for formation of deposits in the nozzle passage 22.

As the gas flows through the nozzle passage 22, the gas is choked at the flow restriction 30. The nozzle passage 22 has the smallest size at the flow restriction 30. The choke location is at or near the proximal end 24 in the nozzle 20 of FIG. 2, and is lower in temperature than the distal end 26. The flow restriction 30 has a size to produce sonic flow or supersonic flow of the gas in the nozzle 20. The size is determined by the flow conditions including gas properties, pressure, temperature, and the like. The gas flow will be choked if the pressure ratio of downstream pressure (P₂) and upstream pressure (P₁) is less than or equal to a constant:

$$\frac{{P}_{2}}{{P}_{1}} \leq {[ \frac{2}{k + 1} ]}^{\frac{k}{k - 1}}$$

For air, the specific heat ratio k is 1.4, and the critical pressure ratio P₂/P₁ is 0.5285. In one example of an HDP CVD process, the chamber pressure is about 5 mTorr, and choke will occur if the diameter of the flow restriction is less than or equal to about 70-100 mil. The gas velocity downstream of the choke or flow restriction 30 will be much higher than that upstream of the flow restriction 30. At the exit of the flow restriction 30, the gas velocity will be the speed of sound:

$$c = \sqrt{\frac{kRT}{{M}_{w}}}$$

where k is the specific heat ratio of the gas, R is the universal gas constant, T is the gas temperature, and M_{w} is the molecular weight of the gas. Due to the high gas velocity, deposits are less likely to form and hence clogging is reduced. The anti-clogging nozzle 20 can provide a much more consistent mass flow of the gas than current nozzles that clog.

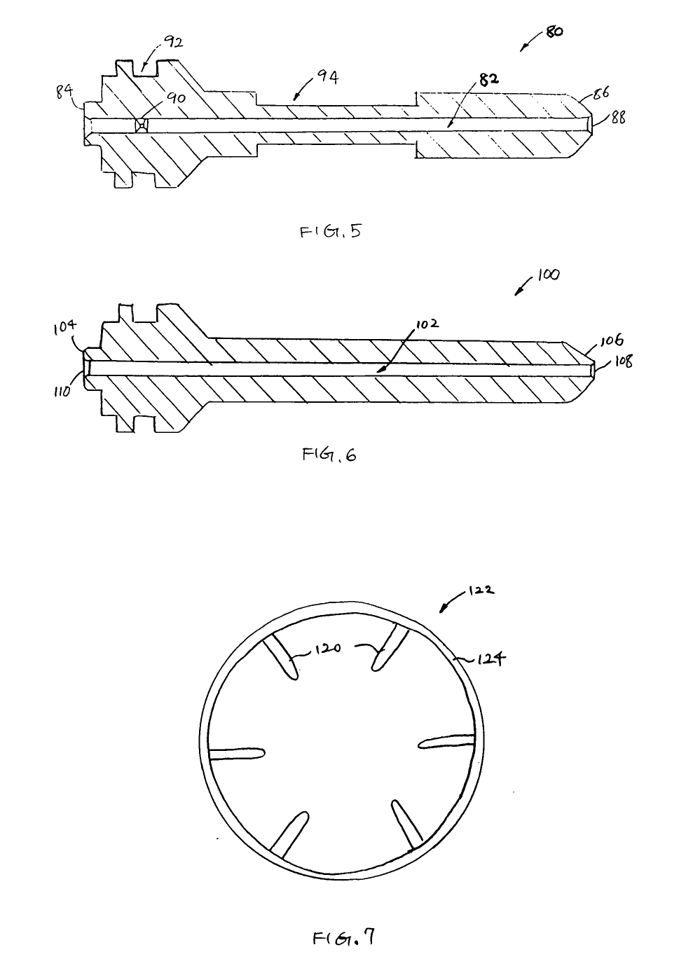

FIG. 3 shows another nozzle 40 which has a nozzle passage 42 that extends from the proximal end 44 to the distal end 46. The distal opening 48 is not restricted. The flow restriction 50 is disposed away from the distal end 46, and is desirably at or near the proximal end 44. In the embodiment shown, the flow restriction 50 is disposed in the proximal region 52 which is connected to the chamber wall or to a water cooled gas distribution ring. As a result, the flow restriction 50 is cooler, desirably much cooler, than the distal region of the nozzle 40, including the distal end 46. The nozzle passage 42 includes a diffuser region 54 adjacent to and downstream of the flow restriction 50. The diffuser region 54 includes a diverging portion distal of the flow restriction 50. The angle α of the diverging portion may be as large as 180°, and is typically about 45° to about 120°. In another nozzle 60 shown in FIG. 4, the diverging portion of the diffuser region 74 downstream of the flow restriction 70 in the nozzle passage 62 has a larger angle than that of the nozzle 40 in FIG. 3. The size of the nozzle passage 42 downstream of the diverging portion may be larger than the size of the nozzle passage 42 upstream. In the nozzles 40, 60 the gas velocities downstream of the flow restriction 50, 70 are higher, and the gas jets are bigger and longer, as compared to the nozzle 20. The larger size at the distal openings 48, 68 further allow the clean gas (e.g., NF₃) to diffuse into the nozzle passages 42, 62 during chamber cleaning. In specific examples, the flow restriction may be about 0.014 inch in diameter and the nozzle passage downstream of the diverging portion of the diffuser region may be about 0.2 inch in diameter.

In FIG. 5, the nozzle 80 has a nozzle passage 82 that extends from the proximal end 84 to the distal end 86. The distal opening 88 is not restricted. The flow restriction 90 is disposed away from the distal end 86, and is desirably at or near the proximal end 84. In the embodiment shown, the flow restriction 90 is disposed in the proximal region 92 which is connected to the chamber wall or to a water cooled gas distribution ring. As a result, the flow restriction 90 is cooler, desirably much cooler, than the distal region of the nozzle 80, including the distal end 86. In addition, a region 94 of reduced cross-section is disposed near the flow restriction 90 or between the flow restriction 90 and the distal end 86. The region 94 reduces heat transfer to the proximal region 92 of the nozzle 80 due to the reduced amount of nozzle material for heat transfer in the region 94 of reduced cross-section. This further lowers the temperature of the choke location for the flow restriction 90.

FIG. 6 shows another nozzle 100 having a nozzle passage 102 that extends from the proximal end 104 to the distal end 106. The distal opening 108 is not restricted. The choke location 110 for choking the gas flow is disposed away from the distal end 106, and is disposed at the proximal end 104. The choke location 110 is cooler, desirably much cooler, than the distal region of the nozzle 100, including the distal end 106. The choke location 110 at the proximal end 104 may have a smaller size than the rest of the nozzle passage 102, but may also have approximately the same size. The size of the proximal end 104 is selected to produce choking at the choke location 110 for a given set of operating conditions including temperature, gas properties, pressure, and the like. In one example, choking occurs at the choking location 110 for a converging gas flow toward the proximal end 104, as long as the size of the nozzle passage 102 at the choke location 110 is about 0.07 inch or less.

FIG. 7 shows a plurality of nozzles 120 distributed around a chamber 122 and connected to the chamber wall 124. The choking locations of the nozzles 120 are moved to cold sections of the nozzles 120 to prevent or reduce clogging. The root cause of clogging is prevented or inhibited because pyrolysis will not occur or will less likely occur at the cold sections. As discussed above, the larger distal opening of the nozzle facilitate cleaning by a clean gas flowing through the distal opening into the nozzle passage. The larger downstream nozzle passage further promotes supersonic flow for better carry distance for deposition on substrates. The anti-clogging nozzle can produce improved deposition on substrates.

The above-described arrangements of apparatus and methods are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A method of introducing a gas into a semiconductor processing chamber, the method comprising:
providing a nozzle having a proximal portion connected to a chamber wall or a gas distribution ring of the semiconductor processing chamber and a distal portion oriented inwardly away from the chamber wall into an interior of the semiconductor processing chamber, the nozzle including a proximal end coupled with a gas supply, the nozzle including a nozzle opening at a distal end, the nozzle including a nozzle passage extending from the proximal end to the distal end;
flowing a gas from the gas supply through the proximal end, the nozzle passage, and the nozzle opening of the nozzle into the interior of the semiconductor processing chamber; and
choking the gas flow through the nozzle passage at a choke location which is spaced away from the distal end.

2. The method of claim 1 wherein the gas flow is choked at or near the proximal end of the nozzle.

3. The method of claim 1 wherein the gas flow is choked at the proximal portion which is connected to the chamber wall.

4. The method of claim 1 wherein the gas flow is choked at a region which is lower in temperature than the distal end of the nozzle.

5. The method of claim 1 wherein choking the gas flow comprises providing a flow restriction in the nozzle passage at the choke location, the flow restriction having a size to produce sonic flow or supersonic flow of the gas in the nozzle.

6. The method of claim 1 wherein choking the gas flow comprises providing a flow restriction in the nozzle passage at the choke location, the nozzle passage having a smallest size at the flow restriction.

7. The method of claim 1 wherein choking the gas flow comprises providing a flow restriction in the nozzle passage at the choke location, and wherein the nozzle passage includes a diffuser region adjacent to and downstream of the flow restriction.

8. The method of claim 7 wherein the diffuser region comprises a diverging portion distal of the flow restriction.

9. The method of claim 8 wherein the diverging portion has an angle of about 45° to about 120°.

10. The method of claim 1 further comprising lowering a temperature of the nozzle near the choke location.

11. The method of claim 10 wherein lowering the temperature of the nozzle at the choke location comprises providing a region of reduced cross-section disposed near the choke location or between the choke location and the distal end of the nozzle.

12. The method of claim 1 further comprising applying energy in the interior of the semiconductor processing chamber to produce a temperature gradient in the nozzle which has a higher temperature in the distal portion than in the proximal portion.

13. The method of claim 12 wherein a temperature at the distal end of the nozzle is substantially higher than a temperature at the proximal portion of the nozzle.

14. The method of claim 13 wherein the temperature at the distal end of the nozzle is at least about twice the temperature at the proximal portion of the nozzle.

15. The method of claim 1 wherein the gas is decomposable to form deposit in the nozzle passage.

16. The method of claim 15 wherein the gas comprises silicon.

17. The method of claim 1 further comprising reducing a pressure in the interior of the semiconductor processing chamber to produce a pressure drop from the proximal end of the nozzle to the distal end of the nozzle.

18. The method of claim 17 wherein a pressure at the proximal end of the nozzle is substantially higher than a pressure at the distal end of the nozzle.

19. The method of claim 18 wherein the pressure at the proximal end of the nozzle is at least about 100 times the pressure at the distal end of the nozzle.

20. A semiconductor processing apparatus comprising:
a semiconductor processing chamber; and
at least one nozzle, each nozzle having a proximal portion connected to a chamber wall of the semiconductor processing chamber and a distal portion oriented inwardly away from the chamber wall into an interior of the semiconductor processing chamber, the nozzle including a proximal end configured to be coupled with a gas supply, the nozzle including a nozzle opening at a distal end, the nozzle including a nozzle passage extending from the proximal end to the distal end, the nozzle including a choke location configured to choke the gas flow through the nozzle passage, the choke location being spaced away from the distal end.

21. The apparatus of claim 20 wherein the choke location is disposed at or near the proximal end of the nozzle.

22. The apparatus of claim 20 wherein the nozzle comprises a flow restriction in the nozzle passage at the choke location, the flow restriction having a size to produce sonic flow or supersonic flow of the gas in the nozzle.

23. The apparatus of claim 20 wherein the nozzle comprises a flow restriction in the nozzle passage at the choke location, the nozzle passage having a smallest size at the flow restriction.

24. The apparatus of claim 20 wherein the nozzle comprises a flow restriction in the nozzle passage at the choke location, and wherein the nozzle passage includes a diffuser region adjacent to and downstream of the flow restriction.

25. The apparatus of claim 24 wherein the diffuser region comprises a diverging portion distal of the flow restriction.

26. The apparatus of claim 25 wherein the diverging portion has an angle of about 45° to about 120°.
